(19) United States
(12) Patent Application Publication
(10) Pub. No.: US 2002/0149032 A1
(43) Pub. Date: Oct. 17, 2002

(54) Fet (field effect transistor) and high frequency module

(76) Inventors: Kiyoshi Ouchi, Kodaira (JP); Tomoyoshi Mishima, Shiki (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/119,015

(22) Filed: Apr. 10, 2002

(30) Foreign Application Priority Data
Apr. 12, 2001 (JP) 2001-113913

(51) Int. Cl. H01L 31/0328; H01L 31/0336; H01L 31/072

(52) U.S. Cl. 257/194

(57) ABSTRACT

In order to provide a high-output field effect transistor having adopted such a structure that a heterointerface between an arsenic compound and a phosphoric compound does not influence the property of a device, and a high-output obtainable high frequency module equipped with MMIC fabricated using the field effect transistor, the field effect transistor having at least a channel layer through which electrons travel, an electron supply layer for supplying electrons to the channel layer, and a buffer layer for flattening the channel layer is provided with an inserted layer larger in bandgap than the buffer layer, which is formed between the buffer layer and the channel layer. This structure can be realized by, for example, achieving the substrate side of the channel layer as an InP layer, the inserted layer as InAlP layer, and the buffer layer as an InAlAs layer respectively.

### BACKGROUND OF THE INVENTION

The present invention relates to a heterojunction field effect transistor capable of obtaining a high output and a high frequency module equipped with a monolithic microwave integrated circuit (hereinafter called “MMIC”) fabricated using the same.

In order to bring an HEMT (High Electron Mobility Transistor) used as an HFET (heterojunction field effect transistor) into a high output, it is known that a high indium composition type channel layer containing indium large in composition ratio is used. An amplifier MMIC in which such a high-output HEMT is brought into high integration, and a high frequency module equipped with the same MMIC have been extensively developed. Since a compound semiconductor having high indium composition, e.g., InGaAs (whose composition of In in III-group elements: 53%, and this will be described below with the term “in III-group elements” being omitted therefrom) is a material having high electron mobility and a high saturated velocity, a current drive ability of a device in which the material is used in the channel layer, is improved and a high output is obtained. Accordingly, the transistor using the high indium composition type channel layer becomes-indispensable to the high-output amplifier MMIC.

Since, however, the InGaAs having the high indium composition is small in bandgap, an avalanche effect-based breakdown is apt to occur in a gate-side portion on the drain side on which an electric field concentrates. The occurrence of the breakdown will lead to a reduction in the breakdown voltage of the device. Thus, when the HEMT having adopted the channel layer is used as a high frequency device that constitutes MMIC, the obtained output is not so much as the output that has been expected.

As a technology for improving the above defect and bringing the amplifier MMIC into the high output, it is known that a channel layer of an HEMT is made up of a double structure of InGaAs and InP. An example of the structure is shown in FIG. 3. An InGaAs layer 5b and an InP layer 5a are placed as channel layers from ones near a gate electrode 13 and InAlAs electron supply layers 6 through 8 to thereby form a composite channel (complex channel).

The principle of operation of the HEMT is as follows. Most of electrons exist in an InGaAs channel low in potential at low source-drain bias voltage. Since InGaAs exhibits an electron transport property excellent in a low electric field as described above, it is convenient for the property of the device. On the other hand, the energy of each electron becomes high at the high source-drain bias voltage, and the rate of electrons that perform real space transition to an InP channel, increases. Since InP is large in bandgap, the breakdown is not produced with ease. It is therefore possible to expect an improvement in breakdown voltage. Further, InP has a property suitable for a channel layer for hot electrons, that a saturated electron velocity in a high field region of 10 keV/cm or more is higher than that of InGaAs.

Thus, the channel layer can be made up of a material having an electron transport property excellent for both the low and high electric fields, and such a channel layer is brought to a high breakdown voltage upon application of a high bias thereto. Therefore, the HEMT having the composite channel can be brought into the high output. A conventional technology related to the HEMT having such a composite channel has been described in, for example, a US document: IEEE Transactions On Electron Devices, Vol. 42, No. 8, pp. 1413-1418 (issued in August 1995).

### SUMMARY OF THE INVENTION

The output of the amplifier MMIC corresponds to a current drive ability and a breakdown voltage of a device to be mounted. Therefore, an MMIC having, as a basic device, the HEMT having the composite channel composed of the two layers of InGaAs and InP is known as the amplifier MMIC aimed to improve the current drive ability and increase the breakdown voltage by the conventional technique. Since the InP channel is high in saturated electron velocity in the high electric field as compared with InGaAs and large in bandgap as described above, it is effective in increasing the breakdown voltage of the HEMT.

In the generally known structure, however, such a structure that InP was grown on the buffer layer based on InAlAs larger in bandgap than InP so as to serve as one of the channel layers, was generally used. In this case, a heterointerface between the channel layer and the buffer layer serves as an interface between an arsenic compound and a phosphoric compound and thereby results in a region in which crystalline defects and misfit dislocations are made dense. Such a region serves as a recombination center and results in a factor of a reduction in breakdown voltage and a noise source. Further, the region leads to the fact that a high output cannot be obtained as designed. The reduction in breakdown voltage will incur a reduction in the output of the amplifier MMIC as a matter of course.

An object of the present invention is to provide a high-output field effect transistor having adopted-such a structure that a heterointerface between an arsenic compound and a phosphoric compound does not influence the property of a device, and a high-output obtainable high frequency module equipped with a monolithic microwave integrated circuit (MMIC) fabricated using the field effect transistor.

The problem on the present invention can be effectively solved by a field effect transistor comprising at least a channel layer through which electrons travel, an electron supply layer for supplying electrons to the channel layer, and a buffer layer for flattening the channel layer, and wherein an inserted layer larger in bandgap than the buffer layer is provided between the buffer layer and the channel layer. This structure can be realized by, for example, forming the substrate side of the channel layer, i.e., the side contacting the inserted layer as an InP layer, the insertion layer as an InAlP layer, and the buffer layer as an InAlAs layer respectively.

The manner of potential energy of the structure provided with such an inserted layer is shown in FIG. 2. Since a heterointerface between the channel layer and the buffer layer results in a heterointerface between phosphoric compounds, misfit dislocations and crystalline defects that result in a recombination center, are little produced as shown in FIG. 2.

Even when a high bias is applied between a source and a drain or a high bias is applied to a gate in this structure, i.e., even when electrons travel through the InP layer, the density of the recombination center at the heterointerface between the channel layer and the buffer layer is suppressed low. It is therefore possible to obtain a breakdown voltage near a value expected from a channel structure.

At this time, a thickness necessary as a minimum for the InAlP inserted layer is a thickness equivalent to the extent that electrons are not tunneled in the InAlAs buffer layer (do not pass therethrough), i.e., a thickness for confining the electrons within the channel layer. A heterointerface on the side of the InAlP inserted layer, which is opposite to the InP channel layer, i.e., an interface with the buffer layer results in a heterointerface between a phosphoric compound and an arsenic compound as in the case of InAlP/InAlAs, and misfit dislocations and crystalline defects concentrate thereon. Since, however, the InAlP inserted layer serves as a potential barrier, electrons little exist in the neighborhood of this interface, the heterointerface between the phosphoric compound and the arsenic compound does not influence the breakdown voltage. Since no electron passes through the interface that serves as the recombination center, noise can be suppressed low.

The high frequency module of the present invention can be realized by mounting an MMIC fabricated by bringing the field effect transistor of the present invention into high integration. Thus, a high-output and low-noise high frequency module can be obtained.

These and other objects and many of the attendant advantages of the invention will be readily appreciated as the same becomes better understood by reference to the following detailed description when considered in connection with the accompanying drawings.

### BRIEF DESCRIPTION OF THE DRAWINGS

FIG. 1 is a cross-sectional view of an embodiment of a field effect transistor (HEMT) according to the present invention;

FIG. 2 is a diagram of the characteristic of the HEMT shown in FIG. 1;

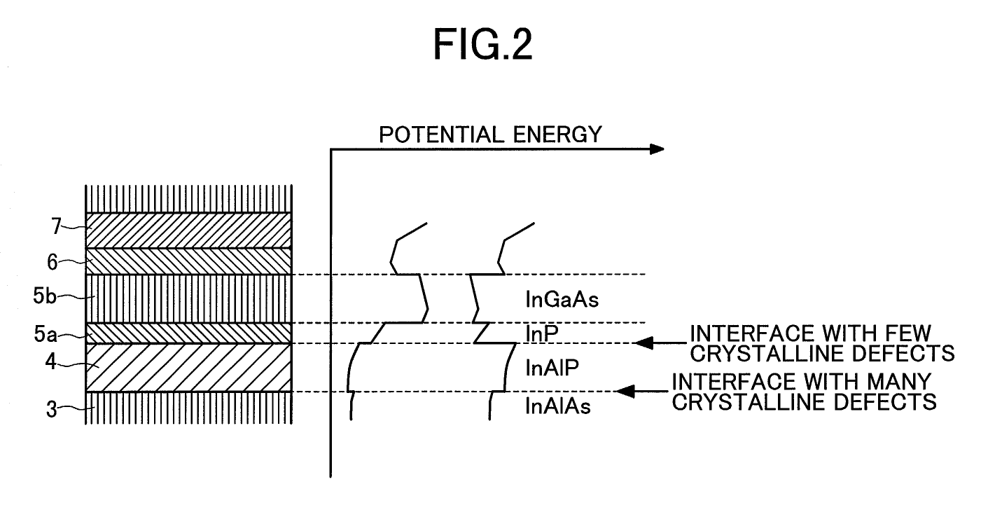

FIG. 3 is a cross-sectional view of a conventional HEMT; and

FIG. 4 is a block diagram of an embodiment of a high frequency module of the present invention.

### DETAILED DESCRIPTION OF THE PREFERRED EMBODIMENTS

A field effect transistor and a high frequency module according to the present invention will hereinafter be described in further details by reference to modes for carrying out the invention, based on embodiments illustrated in the accompanying drawings.

<Embodiment 1>

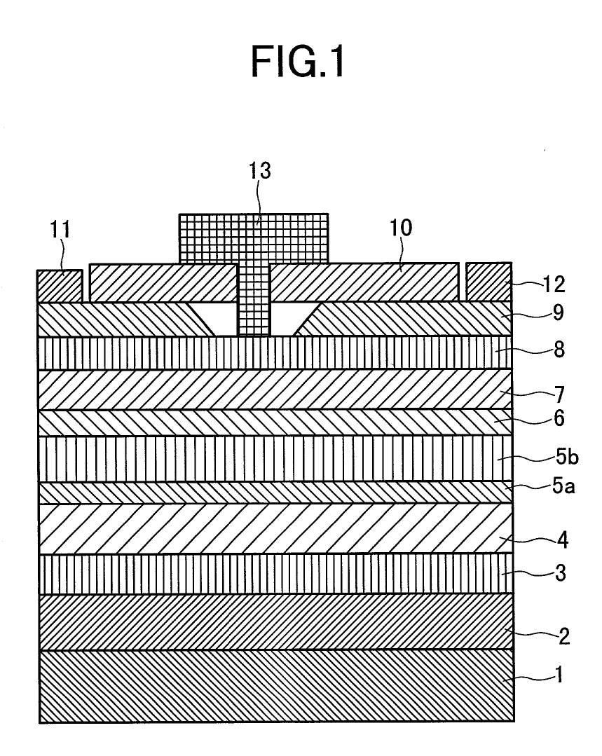

One embodiment to which the present invention is applied, is an HEMT corresponding to a heterojunction field effect transistor. A cross-sectional view thereof is shown in FIG. 1. The present embodiment is integrated into an MMIC which constitutes a high frequency module. In FIG. 1, reference numeral 1 indicates a GaAs substrate. An InAlAs metamorphic layer 2 having a thickness of about 0.6μm is formed on the GaAs substrate, and an undoped InAlAs layer 3 (thickness: 200 nm and In composition: 52%) is formed on the InAlAs metamorphic layer 2 as a buffer layer. A pseudomorphic layer corresponding to an undoped InAlP layer 4 (thickness: 100 nm and In composition: 80%) is inserted as an inserted layer. A composite channel, which is composed of an undoped InP layer 5a (thickness: 10 nm) and an undoped InGaAs layer 5b (thickness: 15 nm and In composition: 53%) , is formed on the inserted layer as a channel layer through which electrons travel. An undoped InAlAs layer 6 (thickness: 2 nm and In composition: 52%), an N type InAlAs layer 7 (doping concentration: 5×10¹⁸/cm³, thickness: 12 nm and In composition: 52%) and an undoped InAlAs layer 8 (thickness: 10 nm and In composition: 20%) , which serve as an electron supply layer, are formed on the composite channel in order. An N type InGaAs layer 9 (doping concentration: 3×10¹⁹/cm³, thickness: 50 nm and In composition: 53%) for reducing contact resistance between an electrode and a semiconductor is formed on the electron supply layer.

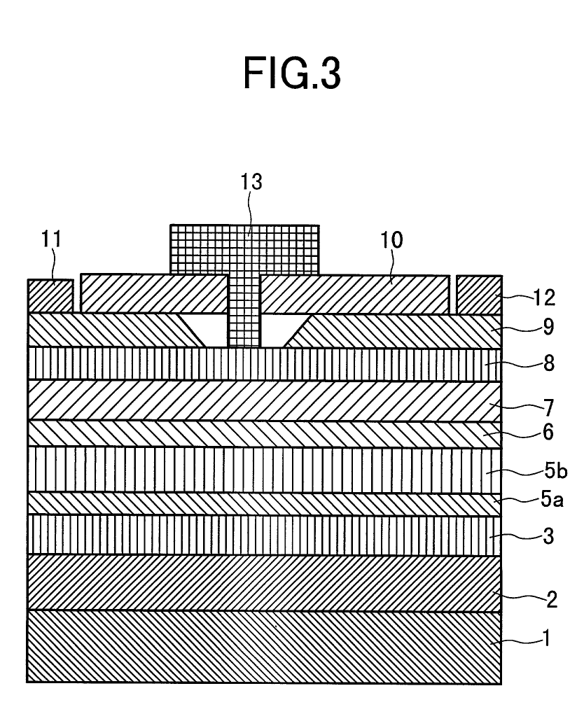

A sample provided with the composite channel and the inserted layer corresponding to the InAlP layer 4 will be called a sample A below. For comparison, an HEMT for the conventional composite channel free of the InAlP layer is fabricated as a sample B. A structure of the sample B is shown in FIG. 3. Further, an HEMT having no InAlP layer and whose channel comprises a single layer of an undoped InGaAs layer (thickness: 40 nm and In composition: 53%) is fabricated as a sample C.

Next, HEMTs are respectively produced according to a common process to be described below with respect to the samples A, B and C. Respective crystalline layers corresponding to layers 2 through 9 shown in FIG. 1, respective crystalline layers corresponding to layers 2 and 3 and layers 5a through 9 shown in FIG. 3, and respective crystalline layers corresponding to the layers 2 and 3 and layers 5b through 9 of FIG. 3 from which the layer 5a is omitted, are first respectively formed on the substrate 1 by epitaxial growth through the use of MBE (molecular beam epitaxy) using a gas source. Incidentally, the respective crystalline layers employed in the present embodiment can be formed by MBE using a solid source or MOCVD (metalorganic chemical vapor deposition) as an alternative.

Subsequently, device-isolation areas are formed by a normal photolithography process and etching. Thereafter, an SiO film 10 (thickness: 400 nm) is formed by CVD (chemical vapor deposition).

Next, areas for a source electrode 11 and a drain electrode 12 are formed by the normal photolithography process. Afterwards, a hole is defined in the SiO film by dry etching and wet etching, followed by evaporation of Au (thickness: 200)/Ti (thickness: 50 nm) thereon and execution of lift-off thereon, whereby the source electrode 11 and the drain electrode 12 are formed.

Thereafter, an opening pattern is formed between the source electrode 11 and the drain electrode 12 by electron-beam lithography. Subsequently, SiO is further deposited on the SiO film by CVD after the hole has been defined in the SiO film by dryetching. The opening is set to 0.15μm by using the normal photolithography process and etching process. Thereafter, the N type InGaAs layer 9 is wet-etched by a citrate etchant and Mo (20 nm) and Al (500nm) are successively evaporated thereon. Afterwards, a patter is formed so as to overlap with the opening of 0.15μm by the normal photolithography process and then etched by an ion milling device, thereby forming a gate electrode 13. A gate length thereof is 0.15μm.

Saturation current densities indicative of current drive abilities of the respective HEMTs are respectively about 800 mA/mm with respect to the samples A, B and C and hence similar values are obtained. As to breakdown voltages, however, the sample A according to the present invention has a breakdown voltage of 6V, the sample B shown in the related art example brought into a composite channel for the purpose of an improvement in breakdown voltage has a breakdown voltage of 2.9V, and the sample C illustrated in the related art example given no breakdown voltage improving technique has a breakdown voltage of 2.3V. It has been revealed from the above that an expected improvement in breakdown voltage has appeared on only the sample A employed in the present embodiment.

Incidentally, the thickness of the respective layers that have epitaxially grown, are not limited to the above in the present invention.

As described above, the present invention is characterized in that a phosphoric material is inserted into a heterointerface between the composite channel formed of the phosphoric compound layer and the buffer layer formed of the arsenic compound layer in such a manner that a crystalline defect developed in the heterointerface does not lead to degradation in breakdown voltage. Thus, the condition for the inserted layer for allowing the present invention to function resides in that phosphor in the V-group elements is first used as a main component, specifically, a composition ratio of the phosphor in the V-group elements (hereinafter described with the term “in the V-group elements” being omitted) is set so as to fall from 50% to 100%. The condition for the inserted layer serves as an electron barrier layer in addition to the above. Namely, the inserted layer absolutely needs to have a large bandgap as compared with the buffer layer and to form a large potential barrier of the conduction bands between the channel and the inserted layer. Preferably, 0.3 eV or more is required.

It is essential that the inserted layer has at least a thickness equivalent to the extent that electrons are unable to tunnel from the channel layer to the buffer layer, i.e., such a thickness that electrons are confined within the channel layer. However, when the inserted layer has lattice mismatch to the buffer layer; the inserted layer needs to have a thickness less than or equal to a critical thickness in which no misfit dislocation occurs.

Accordingly, the inserted layer corresponding to the layer 4 employed in the present embodiment is set to InAlP (thickness: 100 nm and In composition: 80%) from the above viewpoint. Incidentally, the composition of aluminum is lower than the above and set to 10% or more (i.e., the composition ratio of indium: 90% or less) and its upper limit is set to 40% (i.e., the composition ratio of indium: 60% or more), whereby the effect of the present invention can be obtained. The inserted layer may be InGaP whose composition ratio of gallium falls from over 20% to under 40%. If the condition that the inserted layer serves as the potential barrier and is composed principally of the phosphoric compound, is met as described above, then a compound such as InGaAlAsPSb containing arsenic or antimony in the V-group elements may be used.

Even when the metamorphic buffer layer 3 is other than the InAlAs layer, e.g., an AlGaAsSb layer or the like, the inserted layer according to the present invention is effective. This is because even when a V-group mixed crystal composed principally of arsenic or antimony is of the buffer layer, many crystalline defects and misfit dislocations occur in the heterointerface between the buffer layer and the channel layer corresponding to the phosphoric compound.

Further, the substrate employed in the embodiment shown in FIG. 1 is of the GaAs substrate and the InAlAs metamorphic buffer layer 2 has been provided to grow the channel having high indium composition. While the composition of indium in the buffer layer has been changed up to 52% at which lattice match to InP is taken, the composition thereof is not limited to it. A value that ranges from 0% to 52%, can be selected. Owing to such selection, the composition of indium for the channel can freely be determined over a wide range. In such a case, it is desirable that the inserted layer according to the present invention is changed in structure and composition so as to take a band structure suitable for the indium composition of the channel layer.

Incidentally, the substrate 1 can be replaced by an InP substrate. The InAlAs buffer layer 3 whose indium composition is 52%, can easily be grown as a crystal.

While the composite channel has been formed of the undoped InP layer 5a and the undoped InGaAs layer 5b in the HEMT according to the present embodiment, the present invention is not limited to these materials. In addition to the above, the composite channel layer may be formed using an undoped InAsP layer whose composition of phosphor in the V-group elements changes gradedly (smoothly) or stepwise from 100% to 80%, or an undoped InAsP layer whose composition of phosphor is fixed as 80%, as an alternative to the InP layer. Since the potential barrier of electrons existing in the heterointerface between the InAsP channel layer and the InGaAs channel layer becomes small when the InAsP layer is used, an amplifier MMIC can be obtained which suppresses degradation in noise and provides a higher S/N ratio. The field effect transistor of the present invention is capable of obtaining an advantageous effect if the portion that adjoins the inserted layer for the channel layer, is of a compound principally containing phosphor whose composition ratio falls from 50% to 100%.

<Embodiment 2>

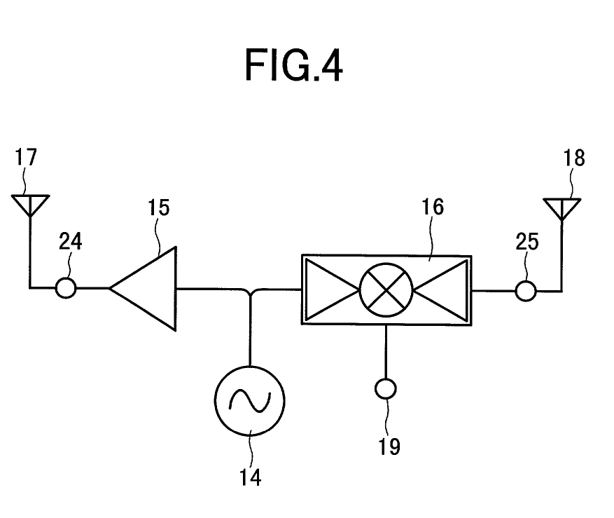

An embodiment of a high frequency module according to the present invention, which is equipped with an MMIC in which the HEMT of the present embodiment has been fabricated as a basic device, will next be described. The present embodiment is configured as a vehicle collision-warning radar module in particular. A circuit configuration thereof is shown in FIG. 4 in the form of a block diagram. In FIG. 4, reference numeral 14 indicates a voltage controlled oscillator, reference numeral 15 indicates an amplifier for amplifying a signal outputted from the voltage controller oscillator 14 and sending the output signal from an output terminal 24 to an external transmitting antenna 17, and reference numeral 16 indicates a receiver for receiving a signal received by an external receiving antenna 18 from an input terminal 25, receiving therein the signal of the voltage controlled oscillator 14, and outputting an intermediate frequency signal (IF signal) to an output terminal 19, respectively. Any of the voltage controlled oscillator 14, the amplifier 15 and the receiver 16 is an MMIC in which the HEMT according to the embodiment is configured as the basic device.

A 76-GHz signal outputted from the voltage controlled oscillator 14 is amplified by the amplifier 15, which is radiated from the transmitting antenna 17. The signal reflected by and thereby returned from an object is amplified by the receiver 16 via the receiving antenna 18 and mixed into a reference signal outputted from the voltage controlled oscillator 14 to thereby produce an IF signal, which in turn is extracted or taken out from the output terminal 19. Another external device calculates a velocity relative to the object, a distance thereto and an angle thereto based on the extracted IF signal.

Since the HEMT of the present invention is used in the vehicle collision-warning radar using the high frequency module according to the present embodiment, the vehicle collision-warding radar is capable of obtaining an increase in output without degradation in noise and providing a 3-dB improvement in S/N ratio as compared with the conventional radar. As a result, the detected distance is improved by 25% and the detected angle is improved by 50% as compared with the conventional radar.

While the embodiments according to the present invention have been described above, the application of the present invention is not limited to the above-described 76-GHz millimeter wave vehicle collision-warning radar. It is needless to say that the present invention can be changed to another type of module in design. The present invention can be applied even to a microwave or millimeter wave wireless communication apparatus, for example. In this case, a communication distance of a wireless system can be made long owing to the application of the present invention, and the number of channels thereof can be increased.

According to the present invention, an HEMT can be realized which is high in breakdown voltage, high in current drive ability and prevents noise degradation. A high frequency module using the same is capable of obtaining high output and high S/N ratio characteristics. When the present module is applied to the millimeter wave vehicle collision-warning radar, a vehicle collision-warding radar system can be obtained which provides high reliability and increases in detected distance and detected angle. When the present module is applied to a wireless communication system, an enlargement of a communication distance and an increase in the number of channels can be achieved.

What is claimed is:

1. A field effect transistor comprising at least:
a channel layer through which electrons travel;
an electron supply layer for supplying electrons to the channel layer; and
a buffer layer for flattening the channel layer,
wherein an inserted layer larger in bandgap than the buffer layer is provided between the buffer layer and the channel layer.

2. The field effect transistor according to claim 1, wherein the channel layer includes a portion contacting the inserted layer, which contains phosphor in V-group elements, having a composition ratio ranging from 50% to 100%, and the inserted layer contains phosphor in the V-group elements, having a composition ratio ranging from 50% to 100%.

3. The field effect transistor according to claim 1, wherein the magnitude of a potential barrier in an interface between the channel layer and the inserted layer is greater than or equal to 0.3 eV, and the inserted layer has such a thickness as to confine electrons in the channel layer.

4. The field effect transistor according to claim 3, wherein the channel layer includes a layer formed of an InP material which contacts the inserted layer, and wherein the inserted layer comprises an InAlP material containing aluminum in III-group elements, having a composition ratio ranging from 10% to 40%, and having a thickness less than or equal to a critical thickness with respect to a lattice constant of InP.

5. The field effect transistor according to claim 3, wherein the channel layer contains a layer formed of an InP material which contacts the inserted layer, and wherein the inserted layer comprises an InGaP material containing gallium in III-group elements, having a composition ratio ranging from 20% to 40%, and which has a thickness less than or equal to a critical thickness with respect to a lattice constant of InP.

6. The field effect transistor according to claim 3, wherein the channel layer comprises a layer formed of an InP material which contacts the inserted layer and a layer formed of an InGaAs material which contacts the electron supply layer.

7. The field effect transistor according to claim 3, wherein the buffer layer is formed of an InAlAs material or an AlGaAsSb material.

8. A high frequency module equipped with a monolithic microwave integrated circuit (MMIC) wherein the field effect transistor of claim 1 is brought into integration.

9. A high frequency module, comprising:
an oscillator monolithic microwave integrated circuit (hereinafter called “MMIC”) for outputting a high frequency signal;
an amplifier MMIC for amplifying the output signal of the oscillator MMIC and outputting the same to the outside; and
a receiver MMIC for mixing a receive signal inputted from outside and amplified and the output signal of the oscillator MMIC together to thereby output an intermediate frequency signal;
wherein at least any of the oscillator MMIC, the amplifier MMIC and the receiver MMIC is composed of field effect transistors of claim 1 which are integrated.
